(19) United States
(12) Patent Application Publication
(10) Pub. No.: US 2026/0020443 A1
(43) Pub. Date: Jan. 15, 2026

(54) DISPLAY PANEL, DISPLAY DEVICE, AND METHOD OF MANUFACTURING DISPLAY PANEL

(71) Applicants: Mianyang HKC Optoelectronics Technology Co.,Ltd., Mianyang (CN); HKC CORPORATION LIMITED, Shenzhen (CN)

(72) Inventors: Xiufeng ZHOU, MIANYANG (CN); Zhisheng XIE, MIANYANG (CN); Yangling TANG, MIANYANG (CN); Qin LIANG, MIANYANG (CN); Zhi YANG, MIANYANG (CN); Haijiang YUAN, MIANYANG (CN)

(73) Assignees: Mianyang HKC Optoelectronics Technology Co.,Ltd., Mianyang (CN); HKC CORPORATION LIMITED, Shenzhen (CN)

(21) Appl. No.: 19/265,236

(22) Filed: Jul. 10, 2025

(30) Foreign Application Priority Data
Jul. 15, 2024 (CN) 202410947292.3

(51) Int. Cl. H10K 59/122; H10K 59/12

(52) U.S. Cl. CPC H10K 59/122; H10K 59/1201

(57) ABSTRACT

A display panel, a display device, and a method of manufacturing the display panel are provided. The display panel includes a dam structure, the dam structure is arranged in the border region and located between the encapsulation structure layer and the driving structure layer. The dam structure includes a first barrier portion and a second barrier portion sequentially stacked in a direction from the driving structure layer to the encapsulation structure layer, an orthographic projection of an edge of a bottom surface of the second barrier portion away from the display region projected onto a top surface of the first barrier portion is located within the top surface of the first barrier portion. An angle between an outer side surface of the second barrier portion away from the display region and the bottom surface of the second barrier portion is an acute angle or a right angle.

### CROSS-REFERENCE TO RELATED APPLICATIONS

This application claims priority to Chinese Patent Application No. 202410947292.3, filed on Jul. 15, 2024, in the National Intellectual Property Administration of China, the contents of which are herein incorporated by reference in their entireties.

### TECHNICAL FIELD

The present disclosure relates to the technical field of displays, in particular, to a display panel, a display device, and a method of manufacturing the display panel.

### BACKGROUND

A light-emitting device, such as organic light emitting diode (OLED), is being increasingly widely applied to products such as televisions and mobile phones due to its characteristics such as lightweight, energy-saving, wide color gamut, high contrast ratio, etc. In the process of manufacturing OLEDs, an isolation structure between pixels is manufactured using a process route involving a maskless overhang structure (i.e., without using masks), so as to improve the display effect of the pixels. When a thin-film encapsulation barrier structure is manufactured by the process route involving the maskless overhang structure, defects such as cracks and voids easily occur in a lower side region of an eave structure within the overhang structure, thereby affecting subsequent processes.

### SUMMARY

Some embodiments of the present disclosure may provide a display panel, a display device, and a method of manufacturing the display panel.

A first technical solution adopted by the present disclosure is to provide a display panel. The display panel has a display region and a border region located around the display region, the display panel includes: a driving structure layer; an encapsulation structure layer, where the driving structure layer and the encapsulation structure layer sequentially are stacked on one another; and a dam structure, arranged in the border region, located between the encapsulation structure layer and the driving structure layer, and including: a first barrier portion; and a second barrier portion. The first barrier portion and the second barrier portion are sequentially stacked in a direction from the driving structure layer to the encapsulation structure layer, an orthographic projection of an edge of a bottom surface of the second barrier portion away from the display region projected onto a top surface of the first barrier portion does not exceed the top surface of the first barrier portion, and an angle between an outer side surface of the second barrier portion away from the display region and the bottom surface of the second barrier portion is an acute angle.

A second technical solution adopted by the present disclosure is to provide a method of manufacturing a display panel. The method includes: obtaining a to-be-processed panel, the to-be-processed panel comprising a driving structure layer and a plurality of overhang structures arranged on a surface of a side of the driving structure layer and spaced apart from each other, each of the plurality of overhang structures comprising a first precursor and a second precursor sequentially stacked on one another, the first precursor being arranged between the second precursor and the driving structure layer, both sides of a bottom of the second precursor extending beyond a top surface of the first precursor, and the driving structure layer having a display region and a border region located around the display region; removing at least a part of the second precursor on a side away from the display region that extends beyond the first precursor to obtain a second barrier portion and obtain a dam structure comprising the first precursor and the second barrier portion; where an angle between an outer side surface of the second barrier portion away from the display region and a bottom surface of the second barrier portion is an acute angle; and forming an encapsulation structure layer on a side of the driving structure layer where the dam structure is arranged.

A third technical solution adopted by the present disclosure is to provide a display device. The display device includes the display panel in the first technical solution and a power supply connected to the display panel and configured to supply power to the display panel.

### BRIEF DESCRIPTION OF THE DRAWINGS

To more clearly illustrate the technical solutions in the embodiments of the present disclosure, a brief introduction to the drawings used in some embodiments of the present disclosure is provided below. It is evident that the drawings described below are only some of the embodiments of the present disclosure. For those skilled in the art, additional drawings may be derived from these drawings without creative work.

FIG. 1 is a schematic planar structural view of a display panel provided by a technical solution in the related art.

FIG. 2 is a schematic cross-sectional view of the display panel in an A-A orientation in the embodiment of FIG. 1.

FIG. 3 is a schematic cross-sectional view of a dam structure according to a first embodiment of the present disclosure.

FIG. 4 is a schematic cross-sectional view of a dam structure according to a second embodiment of the present disclosure.

FIG. 5 is a schematic cross-sectional view of a dam structure according to a third embodiment of the present disclosure.

FIG. 6 is a schematic cross-sectional view of a dam structure according to a fourth embodiment of the present disclosure.

FIG. 7 is a schematic cross-sectional view of a dam structure according to a fifth embodiment of the present disclosure.

FIG. 8 is a schematic cross-sectional view of a dam structure according to a sixth embodiment of the present disclosure.

FIG. 9 is a schematic flowchart of a method of manufacturing a display panel according to some embodiments of the present disclosure.

FIG. 10(a) is a schematic cross-sectional view illustrating some embodiments of operation S1 in FIG. 9.

FIG. 10(b) is a schematic cross-sectional view illustrating some embodiments of operation S1 in FIG. 9.

FIG. 10(c) is a schematic cross-sectional view illustrating some embodiments of operation S1 in FIG. 9.

FIG. 10(d) is a schematic cross-sectional view illustrating some embodiments of operation S1 in FIG. 9.

FIG. 10(e) is a schematic cross-sectional view illustrating some embodiments of operation S1 in FIG. 9.

FIG. 11 is a schematic flowchart of some embodiments of operation S2 in the method of manufacturing the display panel shown in FIG. 9.

FIG. 12(a) is a schematic cross-sectional view corresponding to an operation of some embodiments of operation S2 in FIG. 11.

FIG. 12(b) is a schematic cross-sectional view corresponding to an operation of some embodiments of operation S2 in FIG. 11.

FIG. 12(c) is a schematic cross-sectional view corresponding to an operation of some embodiments of operation S2 in FIG. 11.

FIG. 12(d) is a schematic cross-sectional view corresponding to an operation of some embodiments of operation S2 in FIG. 11.

FIG. 13 is a schematic structural view of a display device according to some embodiments of the present disclosure.

FIG. 14 is a schematic structural view of a display device according to some embodiments of the present disclosure.

### DETAILED DESCRIPTION

The following provides a detailed description of the technical solutions in some embodiments of the present disclosure with reference to the accompanying drawings.

In the following description, specific details such as particular system structures, interfaces, and technologies are presented for illustrative purposes and not for the purpose of limitation, to provide a thorough understanding of the present disclosure.

The technical solutions in some embodiments of the present disclosure will be clearly and completely described below with reference to the accompanying drawings. It is evident that the described embodiments are only part of the embodiments of the present disclosure and not all embodiments. Based on the embodiments of the present disclosure, all other embodiments obtained by those skills in the art without any creative work fall within the scope of the present disclosure.

The terms “first”, “second”, and “third” in some embodiments of the present disclosure are merely used for descriptive purposes and should not be construed as indicating or implying relative importance or implicitly indicating the quantity of the indicated technical features. Thus, the features limited by “first”, “second”, and “third” may explicitly or implicitly include at least one such feature. In the description of the present disclosure, “a plurality of” means at least two, for example, two, three, etc., unless specifically and explicitly limited otherwise. All directional indications (such as up, down, left, right, front, back, etc.) in the embodiments of the present disclosure are only used to explain the relative positional relationships, motion situations, etc., among the components under a specific posture (as shown in the figures). When the specific posture changes, the directional indications shall be changed accordingly. Furthermore, the terms “including” and “having” and any variations thereof are intended to cover non-exclusive inclusion. For example, a process, method, system, product, or device that includes a series of steps or units is not limited to those explicitly listed steps or units but may further optionally include other steps or units not listed, or may further optionally include other inherent steps or units of such process, method, product, or device.

As referred to herein, “embodiment” means that a specific feature, structure, or characteristic described in connection with the embodiment may be included in at least one embodiment of the present disclosure. The appearance of the phrase in various places in the specification are not necessarily all referring to the same embodiment, nor are they mutually exclusive alternative embodiments. It is explicitly and implicitly understood by those skills in the art that the embodiments described herein may be combined with other embodiments.

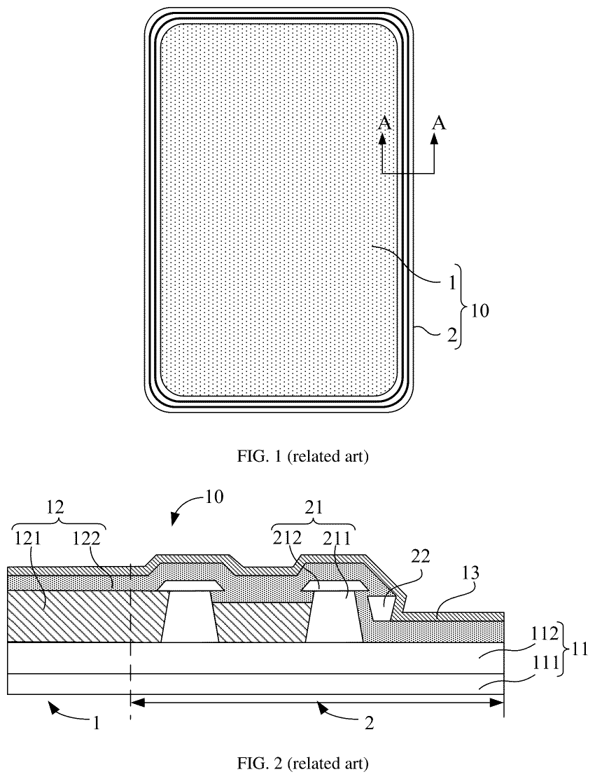

As shown in FIGS. 1 and 2, FIG. 1 is a schematic planar structural view of a display panel provided by a technical solution in the related art. FIG. 2 is a schematic cross-sectional view of the display panel in an A-A orientation in the embodiment of FIG. 1.

At present, when manufacturing a thin-film encapsulation directly through a process route using a maskless overhang structure, defects such as a crack and a void 22 easily occur in a lower side region of an eave structure of the overhang structure. In some embodiments, in a direction substantially perpendicular to a display panel 10, the display panel 10 includes a driving structure layer 11, an encapsulation structure layer 12, and a wiring layer 13 sequentially stacked on one another. The driving structure layer 11 includes a substrate 111 and a driving substrate 112 arranged on the substrate 111. The display panel 10 further includes a barrier structure 21. The barrier structure 21 is arranged in a border region 2 and is located between the driving structure layer 11 and the encapsulation structure layer 12. The barrier structure 21 includes a body structure 211 and a top structure 212 that are sequentially stacked in a direction from the driving structure layer 11 to the encapsulation structure layer 12. Both side edges of the top structure 212 extend beyond a top surface of the body structure 211. The encapsulation structure layer 12 includes an organic encapsulation layer 121 and an inorganic encapsulation layer 122 that are sequentially stacked in a direction away from the driving structure layer 11. The organic encapsulation layer 121 may be an ink jet print (IJP) layer, and the barrier structure 21 is configured to block flow leveling of the organic encapsulation layer 121. The inorganic encapsulation layer 122 is arranged on a surface of a side of the organic encapsulation layer 121 away from the driving structure layer 11. The wiring layer 13 may be arranged on a side of the inorganic encapsulation layer 122 away from the driving structure layer 11. Due to the edges of the top structure 212 of the barrier structure 21 extending beyond the top surface of the body structure 211 to form an eave structure, and due to the barrier structure 21 blocking the organic encapsulation layer 121, it is possible to reduce the occurrence of the organic encapsulation layer 121 flowing to a side of the barrier structure 21 away from the display region 1. Therefore, at a part of the eave structure on a side of the inorganic encapsulation layer 122 away from the display region 1, a part of the inorganic encapsulation layer 122 that extends beyond an end of the top structure 212 is easily to connect with another part of the inorganic encapsulation layer 122 located on the driving structure layer 11, thereby defining a recess among a part of the inorganic encapsulation layer 122 located on an outer side surface of the body structure 211, a part of the inorganic encapsulation layer 122 located on a lower surface of the extended part of the top structure 212, and a part of the inorganic encapsulation layer 122 located on an upper surface of the driving structure layer 11. When the wiring layer 13 is arranged on the encapsulation structure layer 12, the wiring layer 13 covers the recess to form a void 22. When the display panel 10 is heated, due to the thermal expansion and contraction of the air in the void 22, cracks may easily appear in the wiring layer 13, resulting in disconnection of the wiring layer 13 and affecting the reliability of the wiring layer 13.

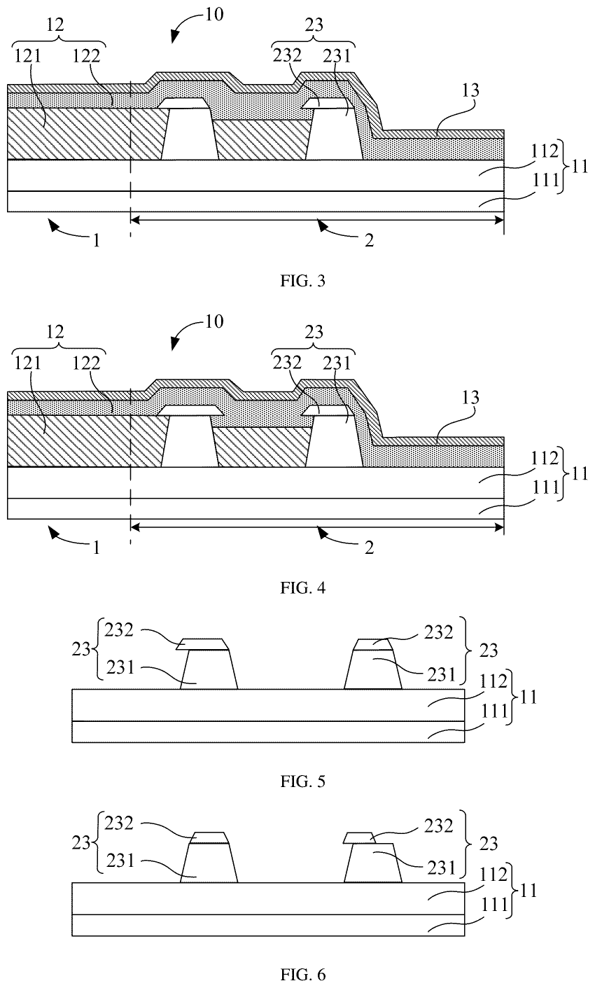

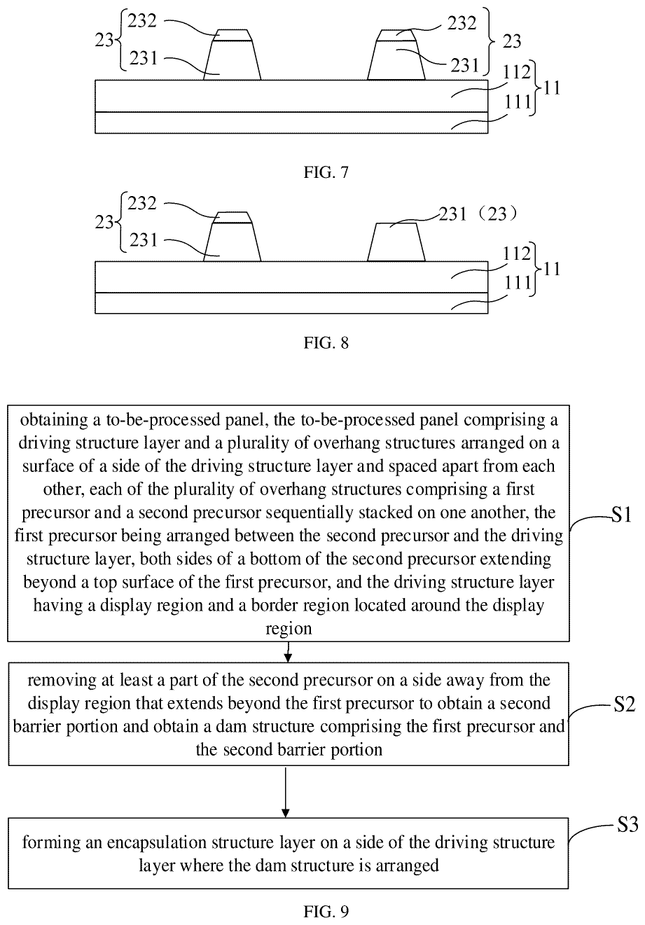

As shown in FIGS. 3 to 8, FIG. 3 is a schematic cross-sectional view of a dam structure according to a first embodiment of the present disclosure, FIG. 4 is a schematic cross-sectional view of a dam structure according to a second embodiment of the present disclosure, FIG. 5 is a schematic cross-sectional view of a dam structure according to a third embodiment of the present disclosure, FIG. 6 is a schematic cross-sectional view of a dam structure according to a fourth embodiment of the present disclosure, FIG. 7 is a schematic cross-sectional view of a dam structure according to a fifth embodiment of the present disclosure, and FIG. 8 is a schematic cross-sectional view of a dam structure according to a sixth embodiment of the present disclosure.

Based on the above problems, some embodiments of the present disclosure provide a display panel 10. The display panel 10 may have a display region 1 and a border region 2 located around or surrounding the display region 1. The display panel 10 may include a driving structure layer 11 and an encapsulation structure layer 12 sequentially stacked on one another. The driving structure layer 11 may include a substrate 111 and a driving substrate 112 arranged on the substrate 111. The display panel 10 may further include a dam structure 23. The dam structure 23 may be arranged in the border region 2 and may be located between the driving structure layer 11 and the encapsulation structure layer 12. The dam structure 23 may include a first barrier portion 231 and a second barrier portion 232 sequentially stacked in a direction from the driving structure layer 11 to the encapsulation structure layer 12. An orthographic projection of an edge of a bottom surface of the second barrier portion 232 away from the display region 1 projected onto a top surface of the first barrier portion 231 may not exceed or may be located within the top surface of the first barrier portion 231 (i.e., the orthographic projection of the edge of the bottom surface of the second barrier portion 232 away from the display region 1 onto the top surface of the first barrier portion 231 is located on a side, which is close to the display region 1, of a side edge of the top surface of the first barrier portion 231 that is away from the display region 1). An angle between an outer side surface of the second barrier portion 232 away from the display region 1 and the bottom surface of the second barrier portion 232 may be an acute angle or a right angle.

In the dam structure 23 provided by some embodiments of the present disclosure, by arranging in such a way that the orthographic projection of the edge of the bottom surface of the second barrier portion 232 away from the display region 1 projected onto the top surface of the first barrier portion 231 does not exceed or may be located within the top surface of the first barrier portion 231 and an angle between the outer side surface of the second barrier portion 232 away from the display region 1 and the bottom surface of the second barrier portion 232 may be an acute angle or a right angle, it may ensure that the outer side surface of the dam structure 23 away from the display region 1 may not form an eave structure, thereby reducing the generation of defects such as cracks and voids formed by the eave structure in the dam structure 23 and improving the encapsulation performance of the display panel 10.

In some embodiments, the display panel 10 may further include a light-emitting device layer, a pixel defining layer, and a conductive isolation structure. The pixel defining layer may be arranged on a side of the driving substrate 112 away from the substrate 111. The light-emitting device layer may include a plurality of light-emitting devices spaced apart from each other. A plurality of pixel openings may be defined on the pixel defining layer. Each light-emitting device may be arranged within a corresponding one of the pixel openings to form a sub-pixel. The conductive isolation structure may be arranged on the pixel defining layer and may be configured to isolate or separate adjacent two sub-pixels from each other, thereby mitigating the problem of optical crosstalk between adjacent two sub-pixels.

In some embodiments, the encapsulation structure layer 12 may be arranged on a side of the dam structure 23 away from the driving substrate 112. In some embodiments, the encapsulation structure layer 12 may be arranged on a side of the driving substrate 112 away from the substrate 111. The encapsulation structure layer 12 may include an organic encapsulation layer 121 and an inorganic encapsulation layer 122 sequentially stacked in a direction away from the driving structure layer 11. In some embodiments, the encapsulation structure layer 12 may include a first inorganic encapsulation layer, the organic encapsulation layer 121, and a second inorganic encapsulation layer sequentially stacked in a direction away from the driving structure layer 11.

The organic encapsulation layer 121 may extend to the border region 2 in a direction away from the display region 1. The dam structure 23 may block the flow leveling or planarization of the organic encapsulation layer 121, thereby reducing the risk of the organic encapsulation layer 121 leveling to an outside of the border region 2. The inorganic encapsulation layer 122 may extend to the border region 2 in a direction away from the display region 1 and may cover an exposed part of the organic encapsulation layer 121.

In some embodiments, the dam structure 23 may be arranged on a surface of the driving substrate 112 away from the substrate 111, that is, the dam structure 23 may be arranged between the driving substrate 112 and the inorganic encapsulation layer 122 and may be covered by the inorganic encapsulation layer 122. A cross-section shape of the first barrier portion 231 of the dam structure 23 in a first direction may include, but may not limited to, a rectangular shape, a trapezoidal shape, an inverted trapezoidal shape, etc. The first direction may be a direction substantially perpendicular to the display panel 10. In some embodiments, in order to improve the reliability of the wiring layer 13 on the encapsulation structure layer 12, an angle between an outer side surface of the first barrier portion 231 away from the display region 1 and a bottom surface of the first barrier portion 231 may be an acute angle or a right angle. In some embodiments, the angle between the outer side surface of the first barrier portion 231 away from the display region 1 and the bottom surface of the first barrier portion 231 may be defined as a first inclination angle. In some embodiments, a range of the first inclination angle may be [30°, 60°] (i.e., greater than or equal to 30 degrees and less than or equal to 60 degrees). The first inclination angle may also be 40 degrees, 45 degrees, 50 degrees, etc.

In some embodiments, an outer side surface of the second barrier portion 232 close to the display region 1 may extend beyond the top surface of the first barrier portion 231. That is, an orthographic projection of an edge of a bottom surface of the second barrier portion 232 close to the display region 1 projected on the driving structure layer 11 may be located between an orthographic projection of a top surface of the first barrier portion 231 projected on the driving structure layer 11 and the display region 1. An outer side surface of the second barrier portion 232 away from the display region 1 may not exceed or extend beyond the top surface of the first barrier portion 231. That is, the orthographic projection of the edge of the bottom surface of the second barrier portion 232 away from the display region 1 projected on the driving structure layer 11 may not exceed or be located within the orthographic projection of the top surface of the first barrier portion 231 projected on the driving structure layer 11.

An angle between the outer side surface of the second barrier portion 232 away from the display region 1 and the bottom surface of the second barrier portion 232 may be an acute angle or a right angle. In some embodiments, the angle between the outer side surface of the second barrier portion 232 away from the display region 1 and the bottom surface of the second barrier portion 232 may be defined as a second inclination angle. A range of the second inclination angle may be [0°, 90°) (i.e., greater than or equal to 0 degrees and less than 90 degrees). In some embodiments, the range of the second inclination angle may be [30°, 60°] (i.e., greater than or equal to 30 degrees and less than or equal to 60 degrees. The second inclination angle may also be 40 degrees, 45 degrees, 50 degrees, etc. The first inclination angle may be equal to or different from the second inclination angle and may be set according to the actual situation.

In some embodiments, in order to further improve the reliability of the wiring layer 13 on the encapsulation structure layer 12 and to mitigate the issue of being prone to disconnection or breakage of the wiring layer 13 on a side of the dam structure 23 away from the display region 1, the angle between the outer side surface of the first barrier portion 231 away from the display region 1 and the bottom surface of the first barrier portion 231 may be not less than, i.e., greater than or equal to the angle between the outer side surface of the second barrier portion 232 away from the display region 1 and the bottom surface of the second barrier portion 232.

In some embodiments, in order to further improve the reliability of the wiring layer 13 on the encapsulation structure layer 12 and to mitigate the issue of being prone to disconnection or breakage of the wiring layer 13 on the side of the dam structure 23 away from the display region 1, a sidewall surface of the dam structure 23 away from the display region 1 may extend close to the display region 1 along the direction away from the driving structure layer 11.

In some embodiments, a distance between an orthographic projection of an outer edge of the bottom surface of the second barrier portion 232 away from the display region 1 projected on the top surface of the first barrier portion 231 and an outer edge of the first barrier portion 231 away from the display region 1 may be non-zero. That is, the outer side surface of the second barrier portion 232 away from the display region 1, a part of the top surface of the first barrier portion 231, and an outer side surface of the first barrier portion 231 away from the display region 1 may cooperatively form a stepped structure, as shown in FIG. 6.

In some embodiments, in order to reduce the probability of forming a step between the first barrier portion 231 and the second barrier portion 232, simplify a connection structure between the first barrier portion 231 and the second barrier portion 232, and reduce the probability of cracks occurring in the encapsulation structure layer 12 arranged at the connection or junction between the first barrier portion 231 and the second barrier portion 232, the outer edge of the bottom surface of the second barrier portion 232 away from the display region 1 may be aligned with the outer edge of the top surface of the first barrier portion 231 away from the display region 1, as shown in FIG. 7.

In some embodiments, a cross-section shape of the second barrier portion 232 of the dam structure 23 in the first direction may be a rectangular shape, a right trapezoidal shape, a scalene trapezoidal shape, an isosceles trapezoidal shape, etc.

In some embodiments, in order to further improve the routing reliability of the wiring layer 13 on the encapsulation structure layer 12, the orthographic projection of the edge of the bottom surface of the second barrier portion 232 close to the display region 1 onto the top surface of the first barrier portion 231 may not exceed or extend beyond the top surface of the first barrier portion 231.

In some embodiments, in order to facilitate the filling of the recess, which is formed by the second barrier portion 232 of the dam structure 23, the first barrier portion 231 of the dam structure 23, and the driving structure layer 11, by the organic encapsulation layer 121 having a flow leveling characteristic, and to reduce the probability of forming the void 22 in the recess, the encapsulation structure may include the organic encapsulation layer 121 and the inorganic encapsulation layer 122 sequentially stacked in the direction away from the driving structure layer 11. A surface of the organic encapsulation layer 121 away from the driving structure layer 11 may be not lower than (i.e., at the same level or at a higher level) the bottom surface of the second barrier portion 232 and not higher than (i.e., at the same level or at a lower level than) a top surface of the second barrier portion 232. In some embodiments, in order to reduce an overflow of the organic encapsulation layer 121 with the flow leveling characteristic to a side of the dam structure 23 away from the display region 1, a surface of the inorganic encapsulation layer 122 away from the driving structure layer 11 may be not higher than (i.e., at the same level or at a lower level than) the top surface of the second barrier portion 232.

In some embodiments, at least one of the first barrier portion 231 and the second barrier portion 232 may be made of a metal material. A material of the first barrier portion 231 may be different from a material of the second barrier portion 232. The materials of the first barrier portion 231 and the second barrier portion 232 may be different metals. In some embodiments, the material of the first barrier portion 231 may be copper, etc., and the material of the second barrier portion 232 may be aluminum, etc. In another embodiment, one of the first barrier portion 231 and the second barrier portion 232 may be made of a metal material, and the other may be made of an insulating material. The metal may include, but may not be limited to, copper and aluminum. The insulating material may include, but may not be limited to, polyimide.

In some embodiments, one dam structure 23 or a plurality of dam structures may be provided. In a case where a plurality of dam structures 23 is provided, the plurality of dam structures 23 may be spaced apart from each another.

In a case where a plurality of dam structures 23 is provided, structural shapes of the plurality of dam structures 23 may be the same or different. In some embodiments, for ease of manufacture, structures, materials, and shapes of the plurality of dam structures 23 may be all the same, as shown in FIGS. 4 to 7.

In some embodiments, in order to improve the encapsulation effect of the encapsulation structure layer 12, the dam structure 23 that is farthest from the display region 1 may include only the first barrier portion 231, as shown in FIG. 8.

At least one parameter selected from the group consisting of the structures, the materials, and the shapes of the plurality of dam structures 23 may also be different from each other.

The encapsulation structure layer 12 that covers the sidewall surface of the dam structure 23 away from the display region 1, as obtained through the above operations, may not have a recess. In some embodiments, the encapsulation structure layer 12 that covers the sidewall surface of the dam structure 23 away from the display region 1 may have an inclined surface, or the encapsulation structure layer 12 that covers the sidewall surface of the dam structure 23 away from the display region 1 may be a stepped structure.

In some embodiments, in order to connect a touch panel in the display panel 10, the display panel 10 may further include the wiring layer 13. The wiring layer 13 may be arranged on a surface of a side of the encapsulation structure layer 12 away from the driving substrate 112. The wiring layer 13 may cover the surface of the side of the encapsulation structure layer 12 and may also cover the part of the encapsulation structure layer 12 on the sidewall surface of the dam structure 23 away from the display region 1. The wiring layer 13 may be in close contact with the encapsulation structure layer 12, such that no void may be formed, thereby improving the reliability of the display panel 10.

Some embodiments of the present disclosure may further provide a method of manufacturing the display panel 10. The display panel 10 may be the display panel 10 provided in the above embodiments. In some embodiments, the method of manufacturing the display panel 10 may include the following operations.

As shown in FIG. 9, FIG. 9 is a schematic flowchart of a method of manufacturing a display panel according to some embodiments of the present disclosure.

At operation S1, a to-be-processed panel may be obtained. The to-be-processed panel may include a driving structure layer and a plurality of overhang structures. The plurality of overhang structures may be arranged on a surface of a side of the driving structure layer and spaced apart from each other. Each overhang structure may include a first precursor (“precursor” is also called as preformed member) and a second precursor sequentially stacked on one another. The first precursor may be arranged between the second precursor and the driving structure layer. Both sides of a bottom of the second precursor may extend beyond a top surface of the first precursor. The driving structure layer may have a display region and a border region located around or surrounding the display region.

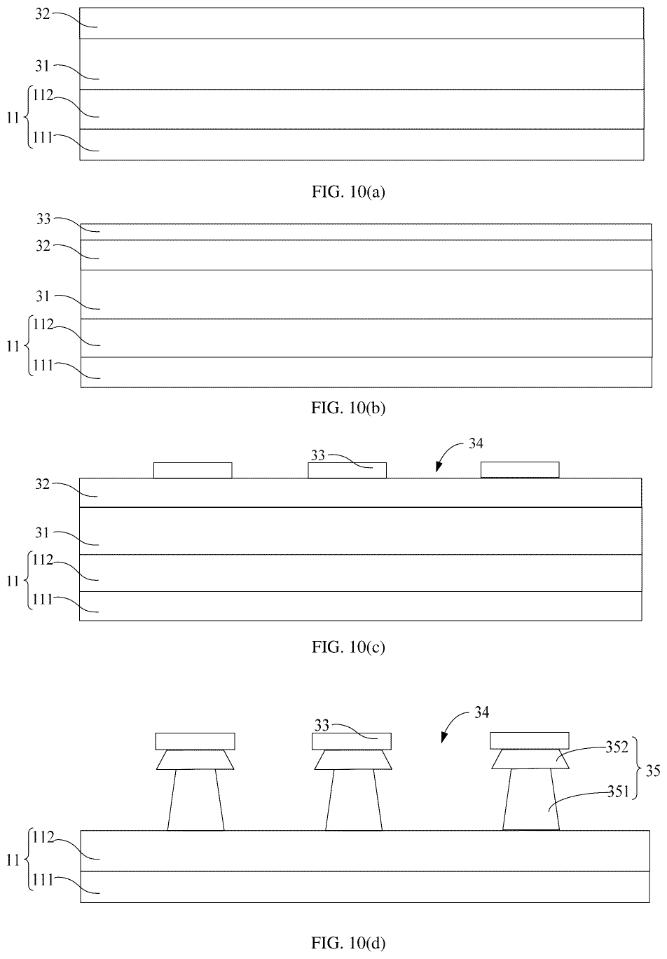

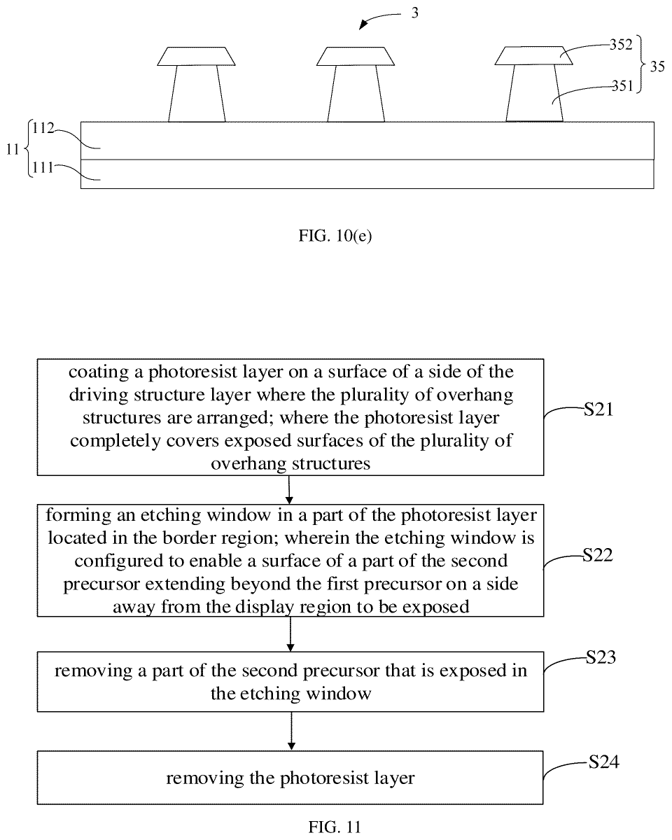

As shown in FIGS. 10(a) to 10(e), FIGS. 10(a) to 10(e) are schematic cross-sectional views illustrating some embodiments of operation S1 in FIG. 9.

In some embodiments, a driving structure layer 11 may be obtained. The driving structure layer 11 may include a substrate 111 and a driving substrate 112 sequentially stacked on one another.

A first functional layer 31 and a second functional layer 32 may be sequentially formed on a surface of a side of the driving structure layer 11 away from the substrate 111. Materials of the first functional layer 31 and the second functional layer 32 may be the same or different. The first functional layer 31 and the second functional layer 32 may be made of metal or insulating material, which may be set according to actual requirements, as shown in FIG. 10(a).

In the following embodiments, an example in which both the first functional layer 31 and the second functional layer 32 may be made of metal may be provided. The materials of the first functional layer 31 and the second functional layer 32 may be different. For example, the first functional layer 31 may be made of copper, and the second functional layer 32 may be made of aluminum.

A first photoresist layer 33 may cover the second functional layer 32. The first photoresist layer 33 may completely cover the second functional layer 32, as shown in FIG. 10(b). A plurality of openings 34 spaced apart from each another may be defined in the first photoresist layer 33. The plurality of openings 34 may be defined by exposure and development. A part of the second functional layer 32 may be exposed via the plurality of openings 34, as shown in FIG. 10(c). The exposed part of the second functional layer 32 may be removed, so that the first functional layer 31 may be exposed through the openings 34. In some embodiments, the exposed part of the second functional layer 32 may be removed by wet etching. The second functional layer 32 may form a plurality of second precursors 352.

The part of the first functional layer 31 exposed through the openings 34 and edges of the first functional layer 31 exposed by the openings 34, i.e., another part of the first functional layer 31 covered by edges of the second precursors 352 may be removed, for example, by wet etching. As a result, the first functional layer 31 may be formed into a plurality of first precursors 351. Each first precursor 351 and a corresponding one of the second precursors 352 may be stacked on one another. In a direction substantially perpendicular to a surface of the driving structure layer 11, a central axis of each first precursor 351 may be aligned with a central axis of the corresponding one of the second precursors 352. A width of each first precursor 351 may be smaller than a width of the corresponding second precursor 352, as shown in FIG. 10(d).

The first photoresist layer 33 may be removed. After the first functional layer 31 and the second functional layer 32 are etched, each first precursor 351 and the corresponding second precursor 352 that are sequentially stacked may form one overhang structure 35. A plurality of overhang structures 35 may be formed on the driving structure layer 11.

Through the above operations, a to-be-processed panel 3 may be obtained, as shown in FIG. 10(e).

At operation S2, at least a part of the second precursor on a side away from the display region that extends beyond the first precursor may be removed, so as to obtain a second barrier portion, thereby forming a dam structure including the first precursor and the second barrier portion.

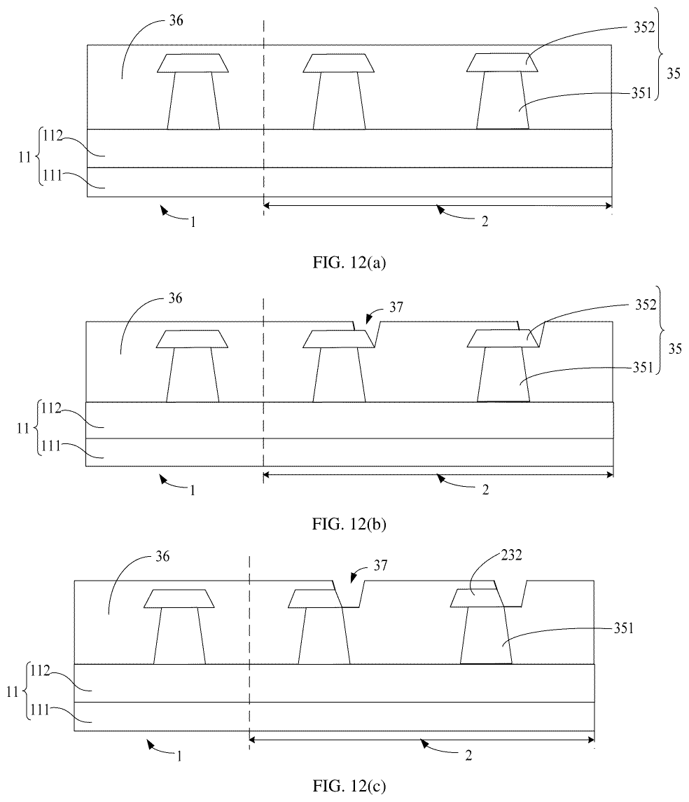

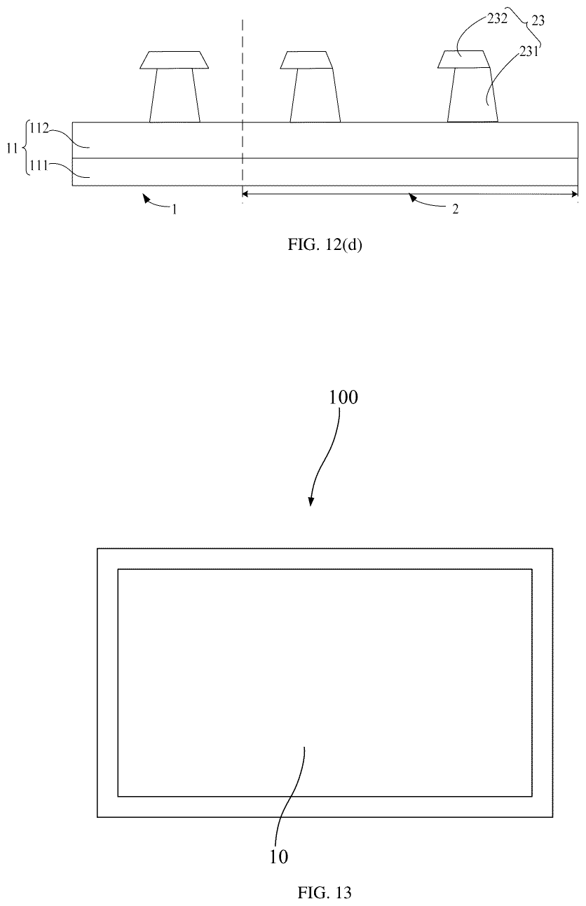

As shown in FIG. 11 and FIGS. 12(a) to 12(d), FIG. 11 is a schematic flowchart of some embodiments of operation S2 in the method of manufacturing the display panel shown in FIG. 9. FIGS. 12(a) to 12(d) are schematic cross-sectional views corresponding to each operation of some embodiments of operation S2 in FIG. 11.

At operation S21, a photoresist layer may be coated on a surface of a side of the driving structure layer where the overhang structure is arranged. The photoresist layer may completely cover exposed surfaces of the overhang structures.

In some embodiments, a photoresist may be coated on a surface of a side of the driving structure layer 11 where the overhang structures 35 are arranged, thereby forming a second photoresist layer 36. The photoresist may fill a gap between the overhang structures 35 and may completely cover a surface of the second precursor 352 away from the first precursor 351, as shown in FIG. 12(a).

At operation S22, an etching window may be formed in a part of the photoresist layer located in the border region. The etching window may be configured to enable a surface of a part of the second precursor extending beyond the corresponding first precursor on a side away from the display region to be exposed.

In some embodiments, an etching window 37 may be formed in a part of the second photoresist layer 36 in the border region 2 by means of, e.g., exposure and development. The etching window 37 may expose only a surface of a part of the second precursor 352 that extends beyond the first precursor 351 on a side away from the display region 1, as shown in FIG. 12(b).

In some embodiments, an etching window 37 may be formed in the part of the second photoresist layer 36 in the border region 2 by means of, e.g., exposure and development. The etching window 37 may be configured to expose a surface of the second precursor 352 on a side of a central axis of the second precursor 352 away from the display region 1.

At operation S23, a part of the second precursor that is exposed in the etching window may be removed.

In some embodiments, the exposed part of the second precursor 352 within the etching window may be removed by means of, e.g., wet etching, enabling the second precursor 352 to be formed into the second barrier portion 232, as shown in FIG. 12(c).

At operation S24, the photoresist layer may be removed.

In some embodiments, the second photoresist layer 36 may be removed. The first precursor 351 may serve as the first barrier portion 231, such that the first barrier portion 231 and the second barrier portion 232 stacked on one another within the border region 2 may cooperatively form the dam structure 23, as shown in FIG. 12(d).

At operation S3, the encapsulation structure layer may be formed on a side of the driving structure layer where the plurality of dam structures are arranged.

In some embodiments, on a side of the driving structure layer 11 where the dam structure 23 is arranged, an organic encapsulation material may be arranged on a surface of the driving structure layer 11 within the display region 1 by means of, e.g., inkjet printing. The organic encapsulation material may be fluid and flow from the display region 1 to the border region 2. When the organic encapsulation material flows to the dam structure 23, the dam structure 23 arranged in the border region 2 may block the organic encapsulation material from overflowing to an outside of the border region 2. As a result, the organic encapsulation material may form an organic encapsulation layer 121 on a side of the dam structure 23 close to the display region 1. An inorganic encapsulation layer 122 may be formed on a surface of the organic encapsulation layer 121 on a side away from the driving structure layer 11 by means of, e.g., chemical vapor deposition. Through the above operations, the encapsulation structure layer 12 may be obtained.

In some embodiments, a metal layer may be formed on a side of the encapsulation structure layer 12 away from the driving structure layer 11 by means of, e.g., spraying, etc. The metal layer may be patterned to obtain the wiring layer 13, as shown in FIG. 3.

Through the above operations, the dam structure 23 and the encapsulation structure layer 12 of the display panel 10 may be manufactured.

As shown in FIG. 13, FIG. 13 is a schematic structural view of a display device according to some embodiments of the present disclosure.

In some embodiments, a display device 100 may be provided. The display device 100 may be configured in fields such as tablets, mobile phones, in-vehicle systems, and lighting.

The display device 100 may include a display panel 10. The configurations and functions of the display panel 10 may be the same as or similar to those of the display panel 10 in the above embodiments, and may achieve the same technical effects. For details, reference may be made to the above detailed description, which will not be repeated here.

The display panel 10 in the display device 100 may adopt the display panel 10 described in the above embodiments. In the display panel 10, the dam structure 23 may be arranged in such a way that an orthographic projection of an edge of a bottom surface of the second barrier portion 232 away from the display region 1 projected onto a top surface of the first barrier portion 231 may not exceed the top surface of the first barrier portion 231 and an angle between an outer side surface of the second barrier portion 232 away from the display region 1 and a bottom surface of the second barrier portion 232 may be an acute angle or a right angle, and thus it may ensure that the outer side surface of the dam structure 23 away from the display region 1 may not form an eave structure, thereby reducing the generation of defects such as cracks and voids formed by the eave structure in the dam structure 23 and improving the encapsulation performance of the display panel 10.

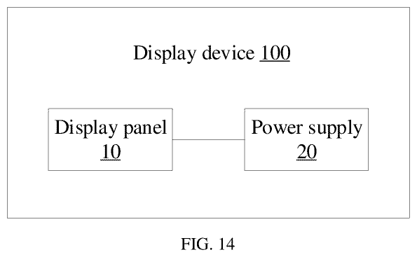

As shown in FIG. 14, FIG. 14 is a schematic structural view of a display device according to some embodiments of the present disclosure. The display device 100 may further include a power supply 20. The power supply 20 may be connected to the display panel 10 and configured to supply power to the display panel 10.

The above are merely embodiments of the present disclosure and are not intended to limit the scope of patent protection of the present disclosure. Any equivalent structural or procedural transformations made based on the content of the specification and drawings of the present disclosure, or any direct or indirect application in other related technical fields, shall likewise fall within the scope of protection of the present disclosure.

1. A display panel, having a display region and a border region located around the display region, the display panel comprising:
a driving structure layer;
an encapsulation structure layer, wherein the driving structure layer and the encapsulation structure layer are sequentially stacked on one another; and
a dam structure, arranged in the border region, located between the encapsulation structure layer and the driving structure layer, and comprising:
a first barrier portion; and
a second barrier portion, wherein the first barrier portion and the second barrier portion are sequentially stacked in a direction from the driving structure layer to the encapsulation structure layer, an orthographic projection of an edge of a bottom surface of the second barrier portion away from the display region projected onto a top surface of the first barrier portion is located within the top surface of the first barrier portion, and an angle between an outer side surface of the second barrier portion away from the display region and the bottom surface of the second barrier portion is an acute angle or a right angle.

2. The display panel as claimed in claim 1, wherein the edge of the bottom surface of the second barrier portion away from the display region is aligned with an edge of a side of the top surface of the first barrier portion away from the display region.

3. The display panel as claimed in claim 1, wherein an angle between an outer side surface of the first barrier portion away from the display region and a bottom surface of the first barrier portion is an acute angle or a right angle, and the angle between the outer side surface of the first barrier portion away from the display region and the bottom surface of the first barrier portion is greater than or equal to the angle between the outer side surface of the second barrier portion away from the display region and the bottom surface of the second barrier portion.

4. The display panel as claimed in claim 1, wherein in a direction away from the driving structure layer, a sidewall surface of the dam structure away from the display region extends toward the display region.

5. The display panel as claimed in claim 1, wherein an orthographic projection of an edge of the bottom surface of the second barrier portion that is close to the display region projected onto the top surface of the first barrier portion is located within the top surface of the first barrier portion, and an angle between an outer side surface of the second barrier portion that is close to the display region and the bottom surface of the second barrier portion is an acute angle or a right angle.

6. The display panel as claimed in claim 1, wherein at least one of the first barrier portion and the second barrier portion is made of a metal material, and a material of the first barrier portion is different from a material of the second barrier portion.

7. The display panel as claimed in claim 1, wherein the encapsulation structure layer comprises an organic encapsulation layer and an inorganic encapsulation layer sequentially stacked in a direction away from the driving structure layer, and a surface of the organic encapsulation layer away from the driving structure layer is greater than or equal to the bottom surface of the second barrier portion and not higher than a top surface of the second barrier portion.

8. The display panel as claimed in claim 1, wherein an orthographic projection of an edge of the bottom surface of the second barrier portion close to the display region projected onto the driving structure layer is located between the display region and an orthographic projection of the top surface of the first barrier portion projected onto the driving structure layer, and the orthographic projection of the edge of the bottom surface of the second barrier portion away from the display region projected onto the driving structure layer is located within the orthographic projection of the top surface of the first barrier portion projected onto the driving structure layer.

9. The display panel as claimed in claim 1, wherein the display panel further comprises a wiring layer, the wiring layer is arranged on a surface of a side of the encapsulation structure layer away from the driving substrate, the wiring layer covers the surface of the side of the encapsulation structure layer and covers a part of the encapsulation structure layer on a sidewall surface of the dam structure away from the display region.

10. The display panel as claimed in claim 1, wherein a distance between the orthographic projection of the edge of the bottom surface of the second barrier portion away from the display region projected onto the top surface of the first barrier portion and an edge of the top surface of the first barrier portion away from the display region is non-zero.

11. A method of manufacturing a display panel, comprising:
obtaining a to-be-processed panel, the to-be-processed panel comprising a driving structure layer and a plurality of overhang structures arranged on a surface of a side of the driving structure layer and spaced apart from each other, each of the plurality of overhang structures comprising a first precursor and a second precursor sequentially stacked on one another, the first precursor being arranged between the second precursor and the driving structure layer, both sides of a bottom of the second precursor extending beyond a top surface of the first precursor, and the driving structure layer having a display region and a border region located around the display region;
removing at least a part of the second precursor on a side away from the display region that extends beyond the first precursor to obtain a second barrier portion and obtain a dam structure comprising the first precursor and the second barrier portion; wherein an angle between an outer side surface of the second barrier portion away from the display region and a bottom surface of the second barrier portion is an acute angle; and
forming an encapsulation structure layer on a side of the driving structure layer where the dam structure is arranged.

12. The method according to claim 11, wherein the removing at least a part of the second precursor on a side away from the display region that extends beyond the first precursor to obtain a second barrier portion and obtain a dam structure comprising the first precursor and the second barrier portion, comprises:
coating a photoresist layer on a surface of a side of the driving structure layer where the plurality of overhang structures are arranged; wherein the photoresist layer completely covers exposed surfaces of the plurality of overhang structures;
forming an etching window in a part of the photoresist layer located in the border region; wherein the etching window is configured to enable a surface of a part of the second precursor extending beyond the first precursor on a side away from the display region to be exposed;
removing a part of the second precursor that is exposed in the etching window; and
removing the photoresist layer.

13. A display device, comprising:
a display panel having a display region and a border region located around the display region, the display panel comprising:
a driving structure layer;
an encapsulation structure layer, wherein the driving structure layer and the encapsulation structure layer are sequentially stacked on one another; and
a dam structure, arranged in the border region, located between the encapsulation structure layer and the driving structure layer, and comprising:
a first barrier portion; and
a second barrier portion, wherein the first barrier portion and the second barrier portion are sequentially stacked in a direction from the driving structure layer to the encapsulation structure layer, an orthographic projection of an edge of a bottom surface of the second barrier portion away from the display region projected onto a top surface of the first barrier portion is located within the top surface of the first barrier portion, and an angle between an outer side surface of the second barrier portion away from the display region and the bottom surface of the second barrier portion is an acute angle or a right angle; and
a power supply, connected to the display panel and configured to supply power to the display panel.

14. The display device as claimed in claim 13, wherein the edge of the bottom surface of the second barrier portion away from the display region is aligned with an edge of a side of the top surface of the first barrier portion away from the display region.

15. The display device as claimed in claim 13, wherein an angle between an outer side surface of the first barrier portion away from the display region and a bottom surface of the first barrier portion is an acute angle or a right angle, and the angle between the outer side surface of the first barrier portion away from the display region and the bottom surface of the first barrier portion is greater than or equal to the angle between the outer side surface of the second barrier portion away from the display region and the bottom surface of the second barrier portion.

16. The display device as claimed in claim 13, wherein in a direction away from the driving structure layer, a sidewall surface of the dam structure away from the display region extends toward the display region.

17. The display device as claimed in claim 13, wherein an orthographic projection of an edge of the bottom surface of the second barrier portion that is close to the display region projected onto the top surface of the first barrier portion is located within the top surface of the first barrier portion, and an angle between an outer side surface of the second barrier portion that is close to the display region and the bottom surface of the second barrier portion is an acute angle or a right angle.

18. The display device as claimed in claim 13, wherein at least one of the first barrier portion and the second barrier portion is made of a metal material, and a material of the first barrier portion is different from a material of the second barrier portion.

19. The display device as claimed in claim 13, wherein the encapsulation structure layer comprises an organic encapsulation layer and an inorganic encapsulation layer sequentially stacked in a direction away from the driving structure layer, and a surface of the organic encapsulation layer away from the driving structure layer is greater than or equal to the bottom surface of the second barrier portion and not higher than a top surface of the second barrier portion.

20. The display device as claimed in claim 13, wherein an orthographic projection of an edge of the bottom surface of the second barrier portion close to the display region projected onto the driving structure layer is located between the display region and an orthographic projection of the top surface of the first barrier portion projected onto the driving structure layer, and the orthographic projection of the edge of the bottom surface of the second barrier portion away from the display region projected onto the driving structure layer is located within the orthographic projection of the top surface of the first barrier portion projected onto the driving structure layer.
